(19) United States
(12) Patent Application Publication
(10) Pub. No.: US 2011/0155221 A1
(43) Pub. Date: Jun. 30, 2011

(54) SOLAR PANEL WITH IMPROVED WATERPROOF DESIGN

(75) Inventors: Hsiang-Yi Yu, Taoyuan City (TW); Wei-Lun Hsiao, Taoyuan City (TW); Hsuan-Ping Chen, Qiaotou Township (TW)

(73) Assignee: DU PONT APOLLO LIMITED, Pak Shek Kok, N.T. (HK)

(21) Appl. No.: 12/979,315

(22) Filed: Dec. 27, 2010

Related U.S. Application Data
(60) Provisional application No. 61/291,454, filed on Dec. 31, 2009.

(51) Int. Cl. H01L 31/048

(52) U.S. Cl. 136/251

(57) ABSTRACT

A solar panel includes a front glass, a photovoltaic film, a back glass, an encapsulant sheet and a weather-resist filler. The photovoltaic film is formed on the front glass. The back glass has a smaller or larger area than the front glass has, but the front and back glasses generally have the same shape. The encapsulant sheet is disposed between the front and back glasses for fully sealing the photovoltaic film and binding the front and back glasses together. When the front and back glasses are overlapped and bound, all bound edges of the front and back glasses define step-like areas. The weather-resist filler is filled onto the step-like areas for fully sealing the encapsulant sheet.

### RELATED APPLICATIONS

This application claims priority to U.S. Provisional Application Ser. No. 61/291,454, filed Dec. 31, 2009, which is herein incorporated by reference.

### BACKGROUND

1. Field of Invention

The present invention relates to a solar panel with a waterproof or weather resistance design.

2. Description of Related Art

In recent years, awareness of ecological problems has been raised worldwide. Among other things, the global warming resulting from CO₂ emission is a serious concern, and clean energy has been increasingly desired. In such a circumstance, a solar cell shows great promise to serve as a source of clean energy in terms of its safety and operability.

When using solar cell modules, durability with respect to the external environment, including temperature, humidity, and impact, is required. Therefore, ordinary solar cell modules are constructed such that: solar cells are sealed with a filler; a weather-resistant film or glass is provided as a protective material on the top surface side thereof; and a reinforcing member or outer member is mounted on the periphery and bottom surface thereof. Most of such members are made of a metal.

As illustrated in FIG. 1, a conventional solar panel 100 is illustrated. Between two glasses (101 and 104), a photovoltaic film 103 and an encapsulant sheet 102 are located. The encapsulant sheet 102 is to enclose the photovoltaic film 103 and to bind two glasses (101 and 104) together. Besides, a weather-resist filler 105 is applied between two glasses (101 and 104) for fully sealing the photovoltaic film 103 and the encapsulant sheet 102. Due to this design, the materials for the weather-resist filler 105 should be compatible with the encapsulant sheet 102 (i.e. using the same materials or materials with similar fusing point) such that the weather-resist filler 105 and encapsulant sheet 102 can be hot pressed between two glasses (101 and 104) with single one step. However, the weather-resist filler 105 may not be good weather-durable such that a water-resist path L is often designed with a length d₁ to guarantee effective weather resistance. When the weather-resist filler 105 occupies more area of the solar panel, there is less area left for depositing photovoltaic films.

For the forgoing reasons, there is a need for improving the solar panel's waterproof or weather resistance design.

### SUMMARY

In accordance with an aspect of the present invention, a solar panel includes a front glass, a photovoltaic film, a back glass, an encapsulant sheet and a weather-resist filler. The photovoltaic film is formed on the front glass. The back glass has a smaller area than the front glass has, but the front and back glasses generally have the same shape. The encapsulant sheet is disposed between the front and back glasses for fully sealing the photovoltaic film and binding the front and back glasses together. When the front and back glasses are overlapped and bound, all bound edges of the front and back glasses define step-like areas. The weather-resist filler is filled onto the step-like areas for fully sealing the encapsulant sheet.

According to one embodiment, the weather-resist filler includes butyl rubber or silicone.

According to another embodiment, the weather-resist filler has a generally triangular cross-section.

According to another embodiment, the encapsulant sheet includes ethylene vinyl acetate or polyvinyl butyral.

According to another embodiment, the back glass has a shorter width and a shorter length than the front glass has.

According to another embodiment, the width of the back glass is at least 16.8 mm shorter than a width of the front glass.

According to another embodiment, the length of the back glass is at least 16.8 mm shorter than a length of the front glass.

In accordance with another aspect of the present invention, a solar panel includes a front glass, a photovoltaic film, a back glass, an encapsulant sheet and a weather-resist filler. The photovoltaic film is formed on the front glass. The back glass has a larger area than the front glass has, but the front and back glasses generally have the same shape. The encapsulant sheet is disposed between the front and back glasses for fully sealing the photovoltaic film and binding the front and back glasses together. When the front and back glasses are overlapped and bound, all bound edges of the front and back glasses define step-like areas. The weather-resist filler is filled onto the step-like areas for fully sealing the encapsulant sheet.

According to one embodiment, the weather-resist filler includes butyl rubber or silicone.

According to another embodiment, the weather-resist filler has a generally triangular cross-section.

According to another embodiment, the encapsulant sheet includes ethylene vinyl acetate or polyvinyl butyral.

According to another embodiment, the back glass has a longer width and a longer length than the front glass has.

According to another embodiment, the width of the back glass is at least 16.8 mm longer than a width of the front glass.

According to another embodiment, the length of the back glass is at least 16.8 mm longer than a length of the front glass.

It is to be understood that both the foregoing general description and the following detailed description are by examples, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 illustrates a cross-sectional view of a conventional solar panel;

FIG. 2 illustrates a cross-sectional view of a solar panel according to one embodiment of the present invention;

FIG. 2A illustrates a top view of the solar panel as illustrated in FIG. 2;

FIG. 3 illustrates a cross-sectional view of a solar panel according to another embodiment of the present invention; and

FIG. 3A illustrates a top view of the solar panel as illustrated in FIG. 3.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

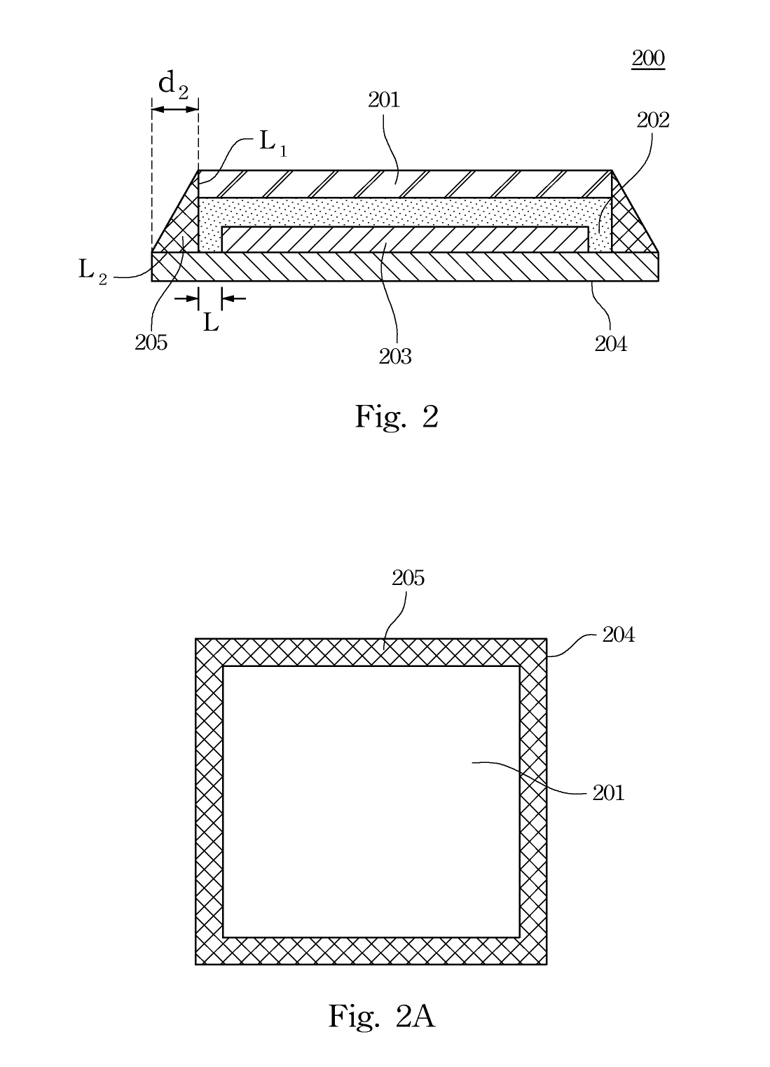

Referring to FIG. 2, which illustrates a cross-sectional view of a solar panel according to one embodiment of the present invention. FIG. 2A illustrates a top view of the solar panel as illustrated in FIG. 2. In order to minimize waterproof or weather-resist design of the solar panel, a new design solar panel 200 includes two glass substrates with different sizes. In this embodiment, the back glass 201 has a smaller area than the front glass 204 has. That is, the back glass 201 has a smaller width and a smaller length compared with the front glass 204. In addition, the back glass 201 is at least 16.8 mm shorter than the front glass 204 in width and length such that the solar panel 200 can has an interface L₂ with a length d₂ larger than 8.4 mm at all edges, which comply with the industrial standard, i.e. IEC 61730-1. In detail, according to the requirement of the International standard IEC 61730-1, the water-resist path is at least 8.4 mm while the maximum system operating voltage is 601-1000 V and at class A. In other words, the industrial standard of the water-resist path is different, depending on the selected maximum system operating voltage and class, which is not used to limit the scope the present invention.

As illustrated in FIG. 2, a photovoltaic film 203 is formed on the front glass 204. The photovoltaic film 203 contains a plurality of photovoltaic cells to convert solar radiation into direct current electricity. An encapsulant sheet 202 (such as ethylene vinyl acetate or polyvinyl butyral) is located between the front and back glasses (204 and 201) for fully sealing the photovoltaic film 203 and binding the front and back glasses (204 and 201) together. When the front and back glasses (204 and 201) are overlapped and bound, all bound edges of the front and back glasses (204 and 201) define step-like areas, i.e. the area where a weather-resist filler 205 has yet been filled. The weather-resist filler 205 is then filled onto the step-like areas for fully sealing the encapsulant sheet 202. As illustrated in FIG. 2A, the weather-resist filler 205 surrounds all edges of the back glass 201. Besides, the front and back glasses (204 and 201) generally have the same shape, e.g. rectangular.

In this embodiment of FIGS. 2 and 2A, the weather-resist filler 205 can be butyl rubber, silicone or other weather-resist materials. Besides, the weather-resist filler 205 has a triangular cross-section, which has an edge in contact with the front glass 204 (which forms an interface L₂) and another edge in contact with the back glass 201 (which forms an interface L₁). Moreover, the “water-resist path” may be defined as the sum of the distance L and L₂, or the sum of the distance L and L₁, in which L is the distance between the edge of the photovoltaic film 203 and the edge of the back glass 201. The interface L₁ can be adjusted by using the back glass 201 of a different thickness.

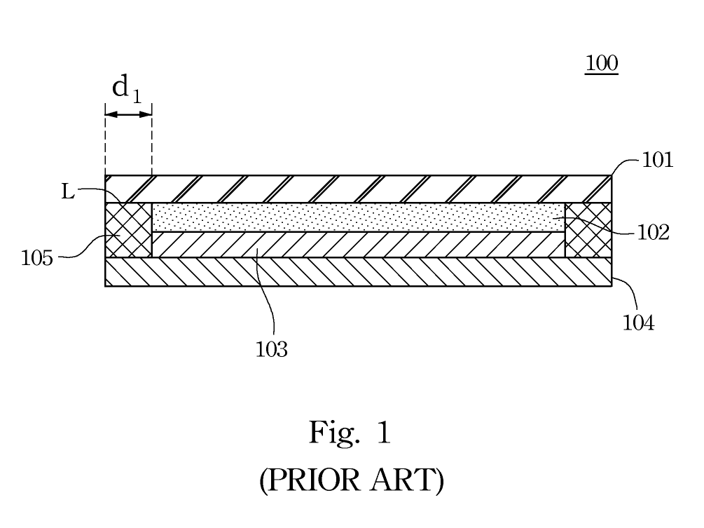

Regarding manufacturing the solar panel 200, it can be slightly different from the solar panel 100 as illustrated in FIG. 1. The weather-resist filler 205 can be filled onto the step-like areas after the hot pressing the front and back glasses (201 and 204) to be bound together. Thus, the weather-resist filler 205 need not necessarily be the materials compatible with the materials, e.g. ethylene vinyl acetate or polyvinyl butyral, for binding the front and back glasses (201 and 204) together. Thus, the materials for the weather-resist filler 205 can be more flexible than the weather-resist materials used to seal the solar panel 100.

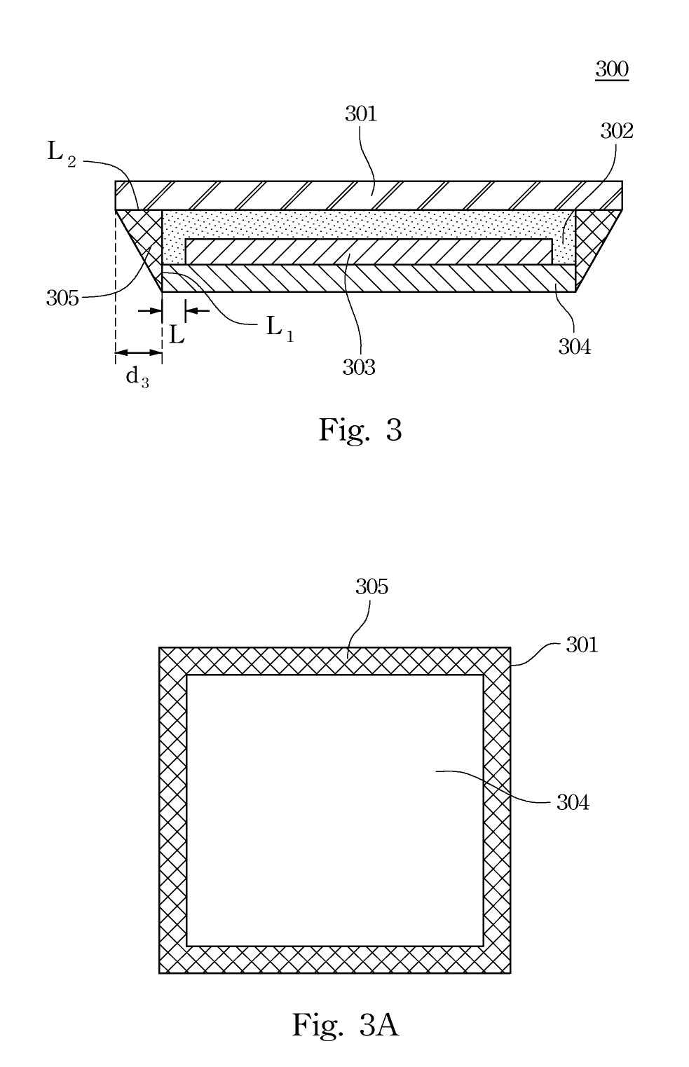

Referring to FIG. 3, which illustrates a cross-sectional view of a solar panel according to one embodiment of the present invention. FIG. 3A illustrates a bottom view of the solar panel as illustrated in FIG. 3. In order to minimize waterproof or weather-resist design of the solar panel, a new design solar panel 300 includes two glass substrates with different sizes. In this embodiment, the back glass 301 has a larger area than the front glass 304 has. That is, the back glass 301 has a longer width and a longer length compared with the front glass 304. In addition, the back glass 301 is at least 16.8 mm longer than the front glass 304 in width and in length such that the solar panel 300 can has an interface L₂ with a length d₃ larger than 8.4 mm at all edges, which comply with the industrial standard, i.e. IEC 61730-1.

As illustrated in FIG. 3, a photovoltaic film 303 is formed on the front glass 304. The photovoltaic film 303 contains a plurality of photovoltaic cells to convert solar radiation into direct current electricity. An encapsulant sheet 302 (such as ethylene vinyl acetate or polyvinyl butyral) is located between the front and back glasses (304 and 301) for fully sealing the photovoltaic film 303 and binding the front and back glasses (304 and 301) together. When the front and back glasses (304 and 301) are overlapped and bound, all bound edges of the front and back glasses (304 and 301) define step-like areas, i.e. the area where a weather-resist filler 305 has yet been filled. The weather-resist filler 305 is then filled onto the step-like areas for fully sealing the encapsulant sheet 302. As illustrated in FIG. 3A, the weather-resist filler 305 surrounds all edges of the front glass 304. Besides, the front and back glasses (304 and 301) generally have the same shape, e.g. rectangular.

In this embodiment of FIGS. 3 and 3A, the weather-resist filler 305 can be butyl rubber, silicone or other weather-resist materials. Besides, the weather-resist filler 305 has a triangular cross-section, which has an edge in contact with the back glass 301 (which forms an interface L₂) and another edge in contact with the front glass 304 (which forms an interface L₁). Moreover, the “water-resist path” may be defined as the sum of the distance L and L₂, or the sum of the distance L and L₁, in which L is the distance between the edge of the photovoltaic film 303 and the edge of the back glass 301. The interface L₁ can be adjusted by using the front glass 304 of a different thickness.

Regarding manufacturing the solar panel 300, it can be slightly different from the solar panel 100 as illustrated in FIG. 1. The weather-resist filler 305 can be filled onto the step-like areas after the hot pressing the front and back glasses (304 and 301) to be bound together. Thus, the weather-resist filler 305 need not necessarily be the materials compatible with the materials, e.g. ethylene vinyl acetate or polyvinyl butyral, for binding the front and back glasses (304 and 301) together. Thus, the materials for the weather-resist filler 305 can be selected more flexibly than the weather-resist materials used to seal the solar panel 100.

Due to the waterproof or weather-resist design disclosed in above-discussed embodiments, the water-resist path (e.g. L+L₁ or L+L₂) not necessarily be such long as used in the prior, but slightly larger than the industrial standard (but is not limited to 8.4 mm). Therefore, the new design waterproof or weather-resist design occupies less area of the solar panel and leaves more areas for depositing photovoltaic films.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A solar panel comprising:
a front glass;
a photovoltaic film formed on the front glass;
a back glass having a smaller area than the front glass has, but the front and back glasses generally having the same shape;
an encapsulant sheet disposed between the front and back glasses for fully sealing the photovoltaic film and binding the front and back glasses together, when the front and back glasses are overlapped and bound, all bound edges of the front and back glasses define step-like areas; and
a weather-resist filler filled onto the step-like areas for fully sealing the encapsulant sheet.

2. The solar panel of claim 1, wherein the weather-resist filler comprises butyl rubber or silicone.

3. The solar panel of claim 1, wherein the weather-resist filler comprises a generally triangular cross-section.

4. The solar panel of claim 1, wherein the encapsulant sheet comprises ethylene vinyl acetate or polyvinyl butyral.

5. The solar panel of claim 1, wherein the back glass has a shorter width and a shorter length than the front glass has.

6. The solar panel of claim 5, wherein the width of the back glass is at least 16.8 mm shorter than a width of the front glass.

7. The solar panel of claim 5, wherein the length of the back glass is at least 16.8 mm shorter than a length of the front glass.

8. A solar panel comprising:
a front glass;
a photovoltaic film formed on the front glass;
a back glass having a larger area than the front glass has, but the front and back glasses generally having the same shape;
an encapsulant sheet disposed between the front and back glasses for fully sealing the photovoltaic film and binding the front and back glasses together, when the front and back glasses are overlapped and bound, all bound edges of the front and back glasses to form step-like areas; and
a weather-resist filler filled onto the step-like areas for fully the sealing encapsulant sheet.

9. The solar panel of claim 8, wherein the weather-resist filler comprises butyl rubber or silicone.

10. The solar panel of claim 8, wherein the weather-resist filler comprises a generally triangular cross-section.

11. The solar panel of claim 8, wherein the encapsulant sheet comprises ethylene vinyl acetate or polyvinyl butyral.

12. The solar panel of claim 8, wherein the back glass has a longer width and a longer length than the front glass has.

13. The solar panel of claim 12, wherein the width of the back glass is at least 16.8 mm longer than a width of the front glass.

14. The solar panel of claim 12, wherein the length of the back glass is at least 16.8 mm longer than a length of the front glass.
